(19) United States
(12) Patent Application Publication
(10) Pub. No.: US 2025/0301608 A1
(43) Pub. Date: Sep. 25, 2025

(54) THERMAL DIFFUSION MEMBER

(71) Applicant: Kitagawa Industries Co., Ltd., Aichi (JP)

(72) Inventors: Kazuki YAMADA, Aichi (JP); Taketo KAWAI, Aichi (JP); Shuchen DONG, Aichi (JP)

(21) Appl. No.: 18/861,113

(22) PCT Filed: Jan. 12, 2023
(86) PCT No.: PCT/JP2023/000613

§ 371 Date: Oct. 28, 2024

(30) Foreign Application Priority Data
Apr. 28, 2022 (JP) 2022-075001

(51) Int. Cl. H05K 7/20

(52) U.S. Cl. CPC H05K 7/2039

(57) ABSTRACT

To provide a thermal diffusion member capable of suppressing generation of a local high-temperature section in the surface of a casing of an electronic device that includes a built-in heat-generating element, and also capable of reducing the temperature of the heat-generating element by 2° C. or more. The thermal diffusion member is a laminated body in which a plurality of layers, including a low-thermal-conductivity layer and a high-thermal-conductivity layer, are laminated. The low-thermal-conductivity layer is formed of a low-thermal-conductivity material sheet having a thermal conductivity in a range from 0.13 to 0.34 W/m·K and a specific heat in a range from 0.9 to 1.67 J/g·K. The high-thermal-conductivity layer is formed of a graphite sheet having a thermal conductivity of 1500 W/m·K or more in a plane direction of the high-thermal-conductivity layer.

### TECHNICAL FIELD

The present disclosure relates to a thermal diffusion member.

### BACKGROUND ART

A composite heat insulator including a graphite film and a low-thermal-conductivity layer is known (for example, see Patent Document 1 below). Patent Document 1 below describes that the temperature of the casing can be significantly reduced by adhering the composite heat insulator to the inner surface of the casing. Further, it is also described that the temperature of a heat-generating component itself can be reduced by using the composite heat insulator.

### CITATION LIST

### Patent Literature

Patent Document 1: JP 2009-111003 A

### SUMMARY OF INVENTION

### Technical Problem

The present inventors experimentally produced composite heat insulators each including a graphite film and a low-thermal-conductivity layer as described above, and checked the performance thereof. As a result, it was possible to reduce the temperature of a casing to a reasonable degree, and it was thus possible to suppress generation of a local high-temperature section called a heat spot, in the surface of the casing.

However, as for the effect of reducing the temperature of a heat-generating component itself, an expected effect could not be obtained. Specifically, although the temperature of the heat-generating component could be slightly reduced by using the composite heat insulator, the effect of reducing the temperature only amounted to approximately less than 2° C. It is generally said that the defect rate of an electronic component increases due to a temperature rise, and for example, it is said that the defect rate increases by 10% only by a temperature rise of 2° C. Therefore, from the viewpoint of reducing the defect rate of the electronic component by 10% or more, it is important to realize a temperature reduction effect of 2° C. or more, and in this respect, there is still room for improvement in the technique described above in Patent Document 1.

In one aspect of the present disclosure, it is desirable to provide a thermal diffusion member capable of suppressing generation of a local high-temperature section in the surface of a casing of an electronic device that includes a built-in heat-generating element, and also capable of reducing the temperature of the heat-generating element by 2° C. or more.

### Solution to Problem

An aspect of the present disclosure is a thermal diffusion member that is a laminated body including a plurality of layers, including a low-thermal-conductivity layer and a high-thermal-conductivity layer which are laminated. The low-thermal-conductivity layer is formed of a low-thermal-conductivity material sheet having a thermal conductivity in a range from 0.13 to 0.34 W/m·K and a specific heat in a range from 0.9 to 1.67 J/g·K. The high-thermal-conductivity layer is formed of a graphite sheet having a thermal conductivity of 1500 W/m·K or more in a plane direction of the high-thermal-conductivity layer.

According to the thermal diffusion member having such a configuration, it is possible to suppress generation of a local high-temperature section in the surface of a casing of an electronic device that includes a built-in heat-generating element, and it is also possible to reduce the temperature of the heat-generating element by 2° C. or more.

Note that the thermal diffusion member of the present disclosure may further include the following configuration.

(A) When the thermal diffusion member is disposed between a casing of an electronic device and a heat-generating element disposed inside the casing, the thermal diffusion member may be oriented to cause the high-thermal-conductivity layer to be on a side of the casing and the low-thermal-conductivity layer to be on a side of the heat-generating element, and may be disposed at a position at which a gap is formed between the low-thermal-conductivity layer and the heat-generating element.

(B) The high-thermal-conductivity layer and the low-thermal-conductivity layer may be bonded to each other via an adhesive layer. The adhesive layer may be formed of a double-sided adhesive sheet, and a thickness of the adhesive layer may be in a range from 0.005 to 0.28 mm.

(C) A protective layer may be provided covering one surface of the low-thermal-conductivity layer on a side opposite to a side of the high-thermal-conductivity layer. The protective layer may be formed of a single-sided adhesive sheet, and a thickness of the protective layer may be in a range from 0.004 to 0.03 mm.

(D) A total thickness of the thermal diffusion member may be in a range from 0.048 to 1 mm.

### BRIEF DESCRIPTION OF DRAWINGS

FIG. 1A is a schematic view illustrating a state in which a thermal diffusion member according to Example 1 is used.

FIG. 1B is an enlarged view of a portion IB illustrated in FIG. 1A.

FIG. 2A is a schematic view illustrating a state in which a thermal diffusion member according to Example 2 is used.

FIG. 2B is an enlarged view of a portion IIB illustrated in FIG. 2A.

FIG. 3A is a schematic view illustrating a state in which a thermal diffusion member according to Example 3 is used.

FIG. 3B is an enlarged view of a portion IIIB illustrated in FIG. 3A.

FIG. 4A is a schematic view illustrating a state in which a thermal diffusion member according to Example 4 is used.

FIG. 4B is an enlarged view of a portion IVB illustrated in FIG. 4A.

FIG. 5A is a schematic view illustrating a state in which a thermal diffusion member according to Example 5 is used.

FIG. 5B is an enlarged view of a portion VB illustrated in FIG. 5A.

FIG. 6A is a schematic view illustrating a state in which a thermal diffusion member according to Example 6 is used.

FIG. 6B is an enlarged view of a portion VIB illustrated in FIG. 6A.

FIG. 7A is a schematic view illustrating a state in which a thermal diffusion member according to Example 7 is used.

FIG. 7B is an enlarged view of a portion VIIB illustrated in FIG. 7A.

FIG. 8A is a schematic view illustrating a state in which a thermal diffusion member according to Example 8 is used.

FIG. 8B is an enlarged view of a portion VIIIB illustrated in FIG. 8A.

FIG. 9A is a schematic view illustrating a state in which a thermal diffusion member according to Example 9 is used.

FIG. 9B is an enlarged view of a portion IXB illustrated in FIG. 9A.

### REFERENCE SIGNS LIST

10, 20, 30, 40, 50, 60, 70, 80, 90 Thermal diffusion member, 1 Casing, 3 Electronic circuit board, 5 heat-generating element, 11, 21, 31, 41, 51, 61, 71, 81, 91 High-thermal-conductivity layer, 12, 22, 32, 42, 52, 62, 72, 82, 92 Low-thermal-conductivity layer, 13A, 23A, 33A, 43A, 53A, 63A, 73A, 83A, 93A First adhesive layer, 13B, 23B, 33B, 43B, 53B, 63B, 73B, 83B, 93B Second adhesive layer, 24, 94 Protective layer, 43C, 53C, 63C Third adhesive layer, 63D Fourth adhesive layer

### DESCRIPTION OF EMBODIMENTS

### Overview of Thermal Diffusion Member

A thermal diffusion member to be described below is disposed, for example, between a casing of an electronic device and a heat-generating element disposed inside the casing. At this time, for example, the thermal diffusion member is oriented such that a high-thermal-conductivity layer is on the casing side and a low-thermal-conductivity layer is on the heat-generating element side, and is disposed at a position at which a gap is formed between the low-thermal-conductivity layer and the heat-generating element. When the heat-generating element generates heat in a state in which the thermal diffusion member is disposed at the above-described position, the heat is transferred from the heat-generating element to the thermal diffusion member due to thermal radiation, and the low-thermal-conductivity layer is heated by the heat.

A low-thermal-conductivity material sheet forming the low-thermal-conductivity layer is a sheet having a low thermal conductivity in a range from 0.13 to 0.34 W/m·K. Therefore, even when a portion in the vicinity of the heat-generating element (hereinafter also referred to as a heated portion) is heated in the low-thermal-conductivity layer, the heat is unlikely to be diffused to the periphery of the heated portion, and only the temperature of the heated portion is likely to rise locally.

Further, the low-thermal-conductivity material sheet forming the low-thermal-conductivity layer is a sheet having a low specific heat in a range from 0.9 to 1.7 J/g·K. Therefore, the low-thermal-conductivity layer has properties of being easily heated and easily cooled. Therefore, the heated portion whose temperature rises locally receives radiant heat from the heat-generating element side and is quickly heated, and at the same time, the heated portion releases heat to the high-thermal-conductivity layer side, via thermal conduction, and is quickly cooled. Thus, as compared with a case in which the heated portion is hard to be cooled, the amount of heat returning from the heated portion to the heat-generating element due to thermal radiation is reduced, and the amount of heat moving from the heat-generating element side to the heated portion side is relatively increased. This contributes to a temperature reduction of the heat-generating element.

The graphite sheet forming the high-thermal-conductivity layer is a sheet having a high thermal conductivity of 1500 W/m·K or more in a plane direction of the high-thermal-conductivity layer. Thus, the heat transferred from the heated portion of the low-thermal-conductivity layer to the high-thermal-conductivity layer is diffused in the plane direction, in the high-thermal-conductivity layer. Therefore, it is possible to inhibit the temperature of only a part of the high-thermal-conductivity layer from rising locally, and it is thus possible to suppress generation of a heat spot at the surface of the casing.

Furthermore, as described above, the low-thermal-conductivity layer is formed of the sheet having the low thermal conductivity. Thus, when the heat is diffused in the plane direction in the high-thermal-conductivity layer, the low-thermal-conductivity layer inhibits the heat from returning to the internal space, of the casing, which is provided on the side opposite to the high-thermal-conductivity layer with the low-thermal-conductivity layer interposed therebetween. In this way, since the heat diffused in the high-thermal-conductivity layer is mainly released from the casing to the outside of the casing, it is possible to suppress a temperature rise in the internal space of the casing. As a result, it is possible to suppress a temperature rise of a member disposed inside the casing (for example, a substrate on which the heat-generating element is mounted, and the like), and this also contributes to the temperature reduction of the heat-generating element.

As long as there is no problem in terms of causing the low-thermal-conductivity layer and the high-thermal-conductivity layer to function effectively, a layer other than the low-thermal-conductivity layer and the high-thermal-conductivity layer may be provided.

An example of the other layer includes an adhesive layer that is interposed between one layer and the other layer and adheres to both the one layer and the other layer in order to bond the one layer and the other layer. More specifically, for example, the high-thermal-conductivity layer and the low-thermal-conductivity layer may be bonded to each other via the adhesive layer. Such an adhesive layer may be formed by using a double-sided adhesive sheet, for example. Alternatively, the adhesive layer may be formed, for example, by applying an adhesive composition having fluidity in a planar form, and then curing the adhesive composition.

When the adhesive layer is formed using a double-sided adhesive sheet, the double-sided adhesive sheet may be, for example, a sheet in which a layer of an adhesive is formed on both surfaces of a planar substrate, or a sheet in which an adhesive alone is formed in a planar shape on both surfaces of the planar substrate. In other words, the adhesive layer itself may have a laminated structure including a plurality of layers, or may be formed by a single layer. For example, as will be described in Examples below, the adhesive layer may be formed of a double-sided adhesive sheet, and may be formed to have a thickness in a range from 0.005 to 0.28 mm. With such a configuration, the low-thermal-conductivity layer and the high-thermal-conductivity layer are caused to function effectively, and an expected effect can be obtained as will be apparent from Examples described below.

Another example of the other layer is, for example, a protective layer that covers one surface of an adjacent layer to protect the adjacent layer. More specifically, for example, on one surface, of the low-thermal-conductivity layer, on the side opposite to the high-thermal-conductivity layer side, a protective layer covering the one surface may be provided. Such a protective layer may be formed by using, for example, a single-sided adhesive sheet. Alternatively, the protective layer may be formed, for example, by applying a coating composition having fluidity in a planar form, and then curing the coating composition.

When the protective layer is formed using a single-sided adhesive sheet, the single-sided adhesive sheet may be, for example, a sheet in which a layer of an adhesive is formed on one side of a planar substrate. In other words, the protective layer itself may have a laminated structure including a plurality of layers. For example, as will be described in Examples below, the protective layer may be formed of a single-sided adhesive sheet, and may be formed to have a thickness in a range from 0.004 to 0.03 mm. With such a configuration, the low-thermal-conductivity layer and the high-thermal-conductivity layer are caused to function effectively, and an expected effect can be obtained as will be apparent from Examples described below.

Furthermore, the thermal diffusion member may be formed to have a total thickness in a range from 0.048 to 1 mm. With such a configuration, the low-thermal-conductivity layer and the high-thermal-conductivity layer are allowed to function effectively, and an expected effect can be obtained as will be apparent from Examples described below.

### EXAMPLES AND COMPARATIVE EXAMPLES

Next, Examples and Comparative Examples will be described.

### Example 1

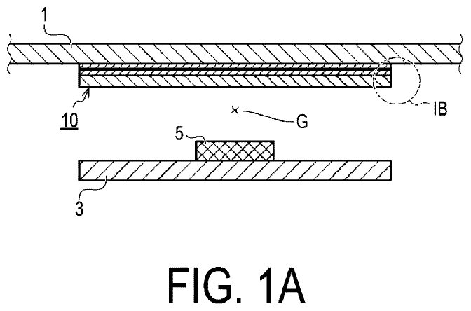

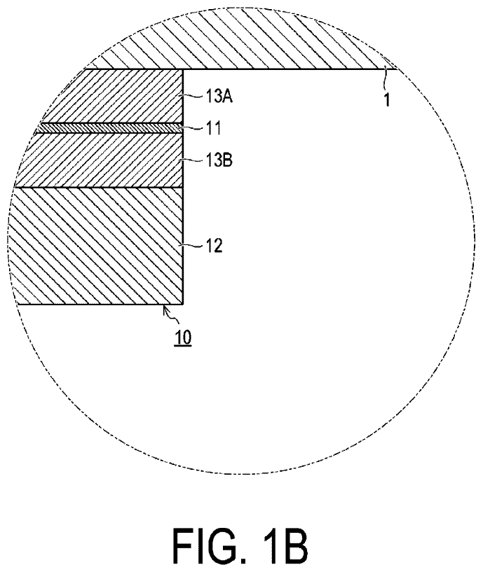

As illustrated in FIG. 1A and FIG. 1B, a thermal diffusion member 10 of Example 1 includes a high-thermal-conductivity layer 11, a low-thermal-conductivity layer 12, a first adhesive layer 13A, and a second adhesive layer 13B. These layers are laminated in the order of the first adhesive layer 13A, the high-thermal-conductivity layer 11, the second adhesive layer 13B, and the low-thermal-conductivity layer 12, thereby forming a laminated body having a four-layer structure.

When the thermal diffusion member 10 is used, for example, as illustrated in FIG. 1A, the thermal diffusion member 10 is disposed between a casing 1 of an electronic device and a heat-generating element 5 mounted on an electronic circuit board 3 inside the casing 1. At this time, as illustrated in FIG. 1A and FIG. 1B, the thermal diffusion member 10 is oriented such that the high-thermal-conductivity layer 11 is on the casing 1 side and the low-thermal-conductivity layer 12 is on the heat-generating element 5 side, and is disposed at a position at which a gap G is formed between the low-thermal-conductivity layer 12 and the heat-generating element 5. When adhering the thermal diffusion member 10 to the casing 1, the adhesive force of the first adhesive layer 13A may be used.

In Example 1, the high-thermal-conductivity layer 11 is formed of a commercially available graphite sheet (Manufacturer name: TGT Co., Product number: TAGS-25, Thickness: 0.025 mm, Thermal conductivity (plane direction): 1600±100 W/m·K, Specific heat (at 50° C.): 0.85 J/g·K). The low-thermal-conductivity layer 12 is formed of a commercially available heat insulating sheet (Manufacturer name: Awa Paper & Technological Company, Inc., Product name: M-thermo heat insulating material I-30F, Thickness: 0.30 mm, Thermal conductivity: 0.13 W/m·K, Specific heat (at 50° C.): 1.67 J/g·K).

Each of the first adhesive layer 13A and the second adhesive layer 13B is formed of a commercially available double-sided adhesive sheet (Manufacturer name: DIC Corporation, Product name: Daitac #8180, Thickness: 0.14 mm, Thermal conductivity: 0.26 W/m·K, Specific heat (at 50° C.): 1.47 J/g·K). This double-sided adhesive sheet is obtained by using a heat-resistant non-woven fabric as a substrate, and forming adhesive surfaces on both sides of the substrate using a highly heat-resistant acrylic adhesive. The total thickness (i.e., the dimension in the lamination direction) of the thermal diffusion member 10 is 0.605 mm.

Note that a specific heat Cₚ (J/g·K) of each layer was measured by a measurement method based on JIS K 7123, using a commercially available differential scanning calorimeter (Manufacturer name: Shimadzu Corporation, Product name: DSC-60 Plus).

Further, a thermal conductivity λ (W/m·K) of the high-thermal-conductivity layer 11 was calculated by the following procedure. First, a thermal diffusivity α (m²/s) of the high-thermal-conductivity layer 11 was measured using a commercially available optical alternating current method thermal diffusivity measuring device (Manufacturer name: Advance Riko, Inc., Product name: LaserPIT). The measurement conditions were as follows: Measurement temperature: room temperature, Atmosphere: air, Number of measurements n: 3, Surface treatment: none, Analysis range: ±1500 to 3000 μm, and Measurement frequency: 10 Hz. Further, a density ρ (kg/m³) of each layer was measured using a commercially available analytical balance (Manufacturer name: Mettler Toledo International Inc., Product name: AG204). Based on the measured values of the thermal diffusivity α, the specific heat Cₚ, and the density ρ, the thermal conductivity λ was calculated using Equation 1 below.

Thermal conductivity λ=thermal diffusivity α×specific heat Cₚ×density ρ [Equation 1]

The thermal conductivity A of each layer (the low-thermal-conductivity layer 12, the first adhesive layer 13A, and the second adhesive layer 13B) other than the high-thermal-conductivity layer 11 was measured using a commercially available rapid thermal conductivity meter (Manufacturer name: Kyoto Electronics Manufacturing Co., Ltd., Product name: QTM-500). In this measurement, a probe (Product number: PD-13) was used to carry out a measurement in the form of a “thin film sample measurement”.

### Example 2

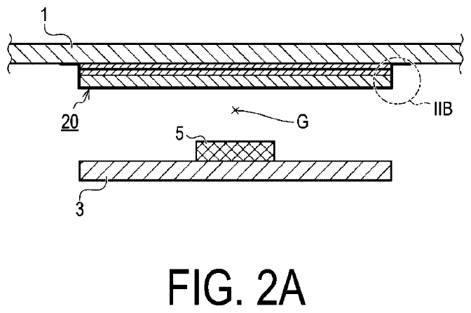

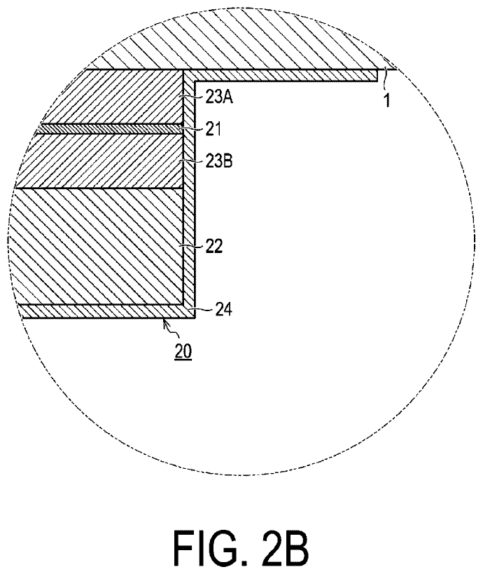

As illustrated in FIG. 2A and FIG. 2B, a thermal diffusion member 20 of Example 2 includes a high-thermal-conductivity layer 21, a low-thermal-conductivity layer 22, a first adhesive layer 23A, a second adhesive layer 23B, and a protective layer 24. These layers are laminated in the order of the first adhesive layer 23A, the high-thermal-conductivity layer 21, the second adhesive layer 23B, the low-thermal-conductivity layer 22, and the protective layer 24, thereby forming a laminated body having a five-layer structure.

As illustrated in FIG. 2B, the protective layer 24 is formed to cover one surface of the low-thermal-conductivity layer 22, end surfaces of each layer included in the thermal diffusion member 20, and further a part of the inner surface of the casing 1. As a result, each of the first adhesive layer 23A, the high-thermal-conductivity layer 21, the second adhesive layer 23B, and the low-thermal-conductivity layer 22 is completely enclosed between the protective layer 24 and the casing 1.

When the above-described protective layer 24 is provided, the one surface of the low-thermal-conductivity layer 22 can be protected, and the end surfaces of the first adhesive layer 23A, the high-thermal-conductivity layer 21, the second adhesive layer 23B, and the low-thermal-conductivity layer 22 can also be protected.

In Example 2, the first adhesive layer 23A, the high-thermal-conductivity layer 21, the second adhesive layer 23B, and the low-thermal-conductivity layer 22 are layers formed in a similar manner to the respective layers exemplified in Example 1. The protective layer 24 is formed of a commercially available single-sided adhesive sheet (Manufacturer name: Teraoka Seisakusho CO., LTD., Product name: polyester-film adhesive tape 631S2 #12, Thickness: 0.03 mm, Thermal conductivity: 0.24 W/m·K, Specific heat (at 50° C.): 2.17 J/g·K). This single-sided adhesive sheet was obtained by using a polyester film (black) having the thickness of 0.012 mm as a substrate, and forming an adhesive surface on one side of the substrate using an acrylic adhesive. The total thickness of the thermal diffusion member 20 is 0.635 mm.

### Example 3

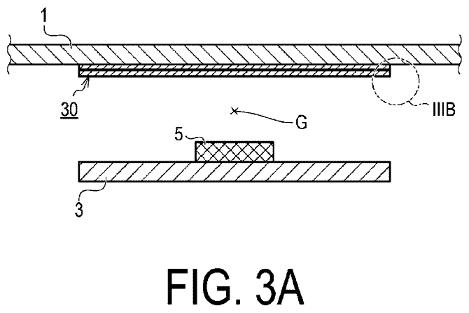

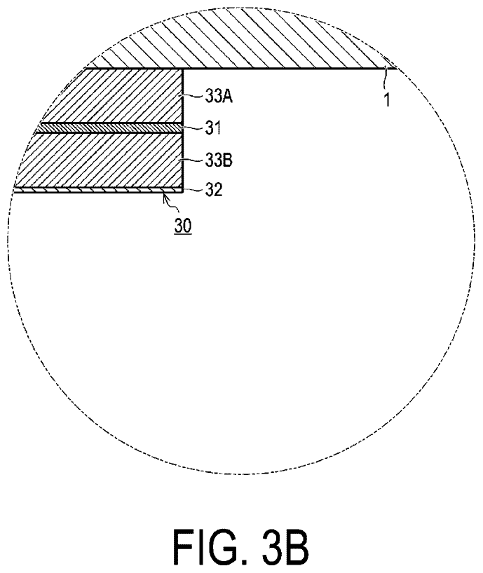

As illustrated in FIG. 3A and FIG. 3B, a thermal diffusion member 30 of Example 3 includes a high-thermal-conductivity layer 31, a low-thermal-conductivity layer 32, a first adhesive layer 33A, and a second adhesive layer 33B. These layers are laminated in the order of the first adhesive layer 33A, the high-thermal-conductivity layer 31, the second adhesive layer 33B, and the low-thermal-conductivity layer 32, thereby forming a laminated body having a four-layer structure.

In Example 3, the first adhesive layer 33A, the high-thermal-conductivity layer 31, and the second adhesive layer 33B are layers formed in a similar manner to the respective layers exemplified in Example 1. The low-thermal-conductivity layer 32 in Example 3 is formed of a commercially available polyimide film (Manufacturer name: Du Pont-Toray Co., Ltd., Product name: Kapton (registered trademark) 50H, Thickness: 0.013 mm, Thermal conductivity: 0.34 W/m·K, Specific heat (at 50° C.): 1.10 J/g·K). The total thickness of the thermal diffusion member 30 is 0.318 mm.

When the low-thermal-conductivity layer 32 is formed of a polyimide film as in Example 3, the thickness of the low-thermal-conductivity layer 32 can be reduced as compared with the low-thermal-conductivity layer 12 of Example 1, and thus the thickness of the thermal diffusion member 30 can be reduced. Further, since the polyimide film is excellent in mechanical strength and chemical strength, when the low-thermal-conductivity layer 32 is formed of the polyimide film, the low-thermal-conductivity layer 32 plays the same role as the protective layer 24 exemplified in Example 2. That is, the low-thermal-conductivity layer 32 functions as a low-thermal-conductivity layer-cum-protective layer. Note that although the protective layer 24 exemplified in Example 2 is formed to cover the end surfaces of the thermal diffusion member 20 and the part of the inner surface of the casing 1, the low-thermal-conductivity layer 32 exemplified in Example 3 may also be formed to cover the end surfaces of the thermal diffusion member 30 and a part of the inner surface of the casing 1.

### Example 4

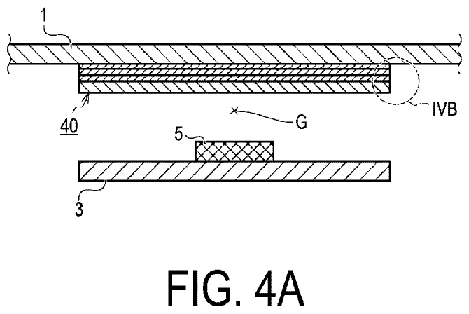

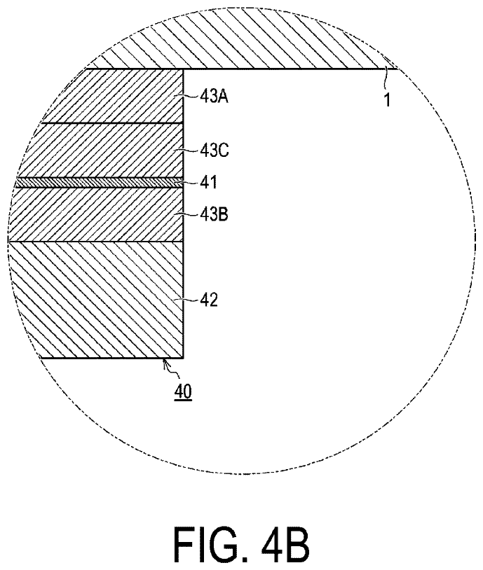

As illustrated in FIG. 4A and FIG. 4B, a thermal diffusion member 40 of Example 4 includes a high-thermal-conductivity layer 41, a low-thermal-conductivity layer 42, a first adhesive layer 43A, a second adhesive layer 43B, and a third adhesive layer 43C. These layers are laminated in the order of the first adhesive layer 43A, the third adhesive layer 43C, the high-thermal-conductivity layer 41, the second adhesive layer 43B, and the low-thermal-conductivity layer 42, thereby forming a laminated body having a five-layer structure.

In Example 4, the first adhesive layer 43A, the high-thermal-conductivity layer 41, the second adhesive layer 43B, and the low-thermal-conductivity layer 42 are layers formed in a similar manner to the respective layers in Example 1. The third adhesive layer 43C is formed of the same sheet material as the first adhesive layer 43A and the second adhesive layer 43B. A difference from Example 1 is that the third adhesive layer 43C is added between the first adhesive layer 43A and the high-thermal-conductivity layer 41. That is, a portion formed only by the first adhesive layer 13A in Example 1 is formed by the first adhesive layer 43A and the third adhesive layer 43C in Example 4, and thus the portion is twice as thick as that in Example 1. The total thickness of the thermal diffusion member 40 is 0.745 mm.

### Example 5

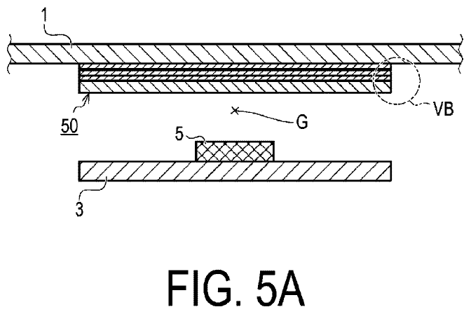

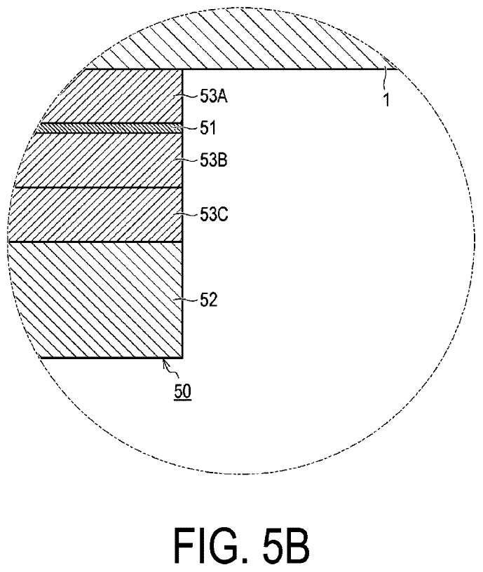

As illustrated in FIG. 5A and FIG. 5B, a thermal diffusion member 50 of Example 5 includes a high-thermal-conductivity layer 51, a low-thermal-conductivity layer 52, a first adhesive layer 53A, a second adhesive layer 53B, and a third adhesive layer 53C. These layers are laminated in the order of the first adhesive layer 53A, the high-thermal-conductivity layer 51, the second adhesive layer 53B, the third adhesive layer 53C, and the low-thermal-conductivity layer 52, thereby forming a laminated body having a five-layer structure.

In Example 5, the first adhesive layer 53A, the high-thermal-conductivity layer 51, the second adhesive layer 53B, and the low-thermal-conductivity layer 52 are layers formed in a similar manner to the respective layers in Example 1. The third adhesive layer 53C is formed of the same sheet material as the first adhesive layer 53A and the second adhesive layer 53B. A difference from Example 1 is that the third adhesive layer 53C is added between the second adhesive layer 53B and the low-thermal-conductivity layer 52. That is, a portion formed only by the second adhesive layer 13B in Example 1 is formed by the second adhesive layer 53B and the third adhesive layer 53C in Example 5, and thus the portion is twice as thick as that in Example 1. The total thickness of the thermal diffusion member 50 is 0.745 mm.

### Example 6

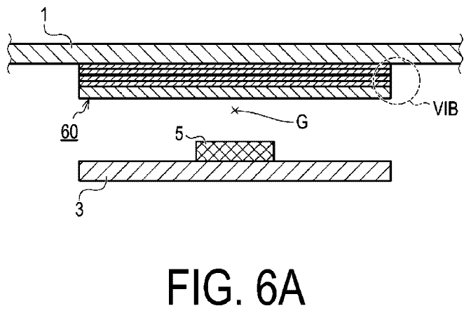

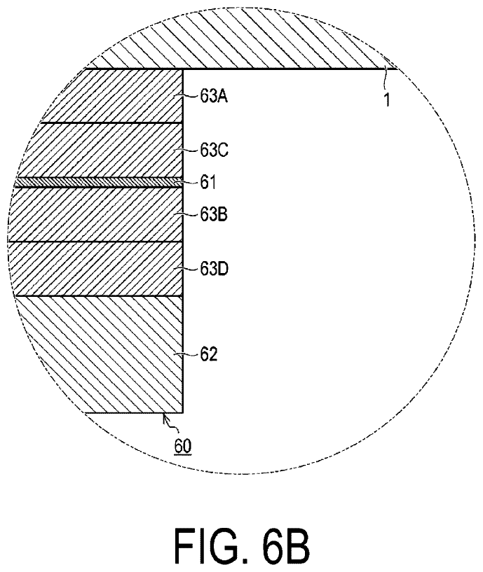

As illustrated in FIG. 6A and FIG. 6B, a thermal diffusion member 60 of Example 6 includes a high-thermal-conductivity layer 61, a low-thermal-conductivity layer 62, a first adhesive layer 63A, a second adhesive layer 63B, a third adhesive layer 63C, and a fourth adhesive layer 63D. These layers are laminated in the order of the first adhesive layer 63A, the third adhesive layer 63C, the high-thermal-conductivity layer 61, the second adhesive layer 63B, the fourth adhesive layer 63D, and the low-thermal-conductivity layer 62, thereby forming a laminated body having a six-layer structure.

In Example 6, the first adhesive layer 63A, the high-thermal-conductivity layer 61, the second adhesive layer 63B, and the low-thermal-conductivity layer 62 are layers formed in a similar manner to the respective layers in Example 1. The third adhesive layer 63C and the fourth adhesive layer 63D are formed of the same sheet material as the first adhesive layer 63A and the second adhesive layer 63B. A difference from Example 1 is that the third adhesive layer 43C is added between the first adhesive layer 43A and the high-thermal-conductivity layer 41, and the fourth adhesive layer 63D is added between the second adhesive layer 63B and the low-thermal-conductivity layer 62.

That is, the portion formed only by the first adhesive layer 13A in Example 1 is formed by the first adhesive layer 43A and the third adhesive layer 43C in Example 6, and thus the portion is twice as thick as that in Example 1. Further, the portion formed only by the second adhesive layer 13B in Example 1 is formed by the second adhesive layer 63B and the fourth adhesive layer 63D in Example 6, and thus the portion is twice as thick as that in Example 1. The total thickness of the thermal diffusion member 60 is 0.885 mm.

### Example 7

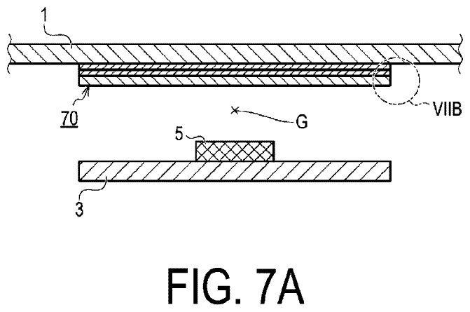

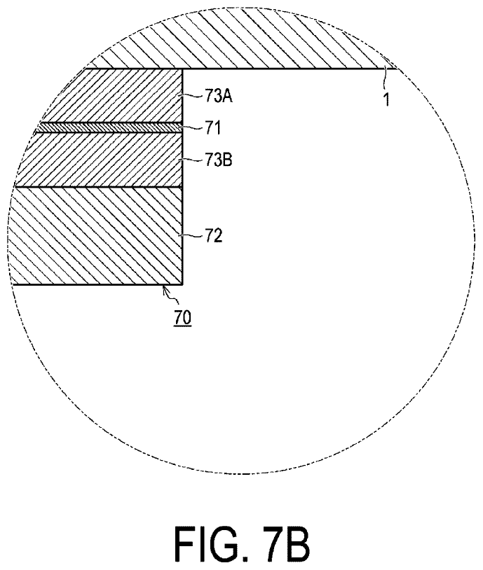

As illustrated in FIG. 7A and FIG. 7B, a thermal diffusion member 70 of Example 7 includes a high-thermal-conductivity layer 71, a low-thermal-conductivity layer 72, a first adhesive layer 73A, and a second adhesive layer 73B. These layers are laminated in the order of the first adhesive layer 73A, the high-thermal-conductivity layer 71, the second adhesive layer 73B, and the low-thermal-conductivity layer 72, thereby forming a laminated body having a four-layer structure.

In Example 7, the first adhesive layer 73A, the high-thermal-conductivity layer 71, and the second adhesive layer 73B are layers formed in a similar manner to the respective layers exemplified in Example 1. The low-thermal-conductivity layer 72 in Example 7 is formed of commercially available nonflammable paper (Manufacturer name: TIGEREX Co., Ltd., Product name: nonflammable paper GP (GP18), Thickness: 0.25 mm, Thermal conductivity: 0.29 W/m·K, Specific heat (at 50° C.): 1.17 J/g·K). The total thickness of the thermal diffusion member 70 is 0.595 mm.

### Example 8

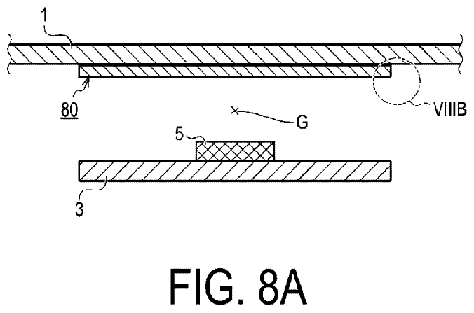

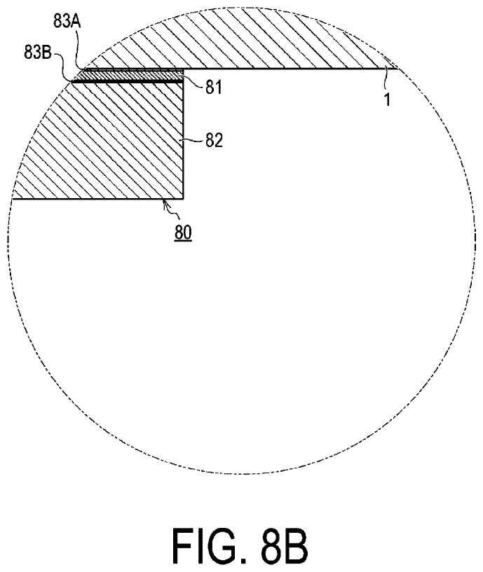

As illustrated in FIG. 8A and FIG. 8B, a thermal diffusion member 80 of Example 8 includes a high-thermal-conductivity layer 81, a low-thermal-conductivity layer 82, a first adhesive layer 83A, and a second adhesive layer 83B. These layers are laminated in the order of the first adhesive layer 83A, the high-thermal-conductivity layer 81, the second adhesive layer 83B, and the low-thermal-conductivity layer 82, thereby forming a laminated body having a four-layer structure.

In Example 8, the high-thermal-conductivity layer 81 and the low-thermal-conductivity layer 82 are layers formed in a similar manner to the respective layers exemplified in Example 1. Each of the first adhesive layer 83A and the second adhesive layer 83B in Example 8 is formed of a commercially available double-sided adhesive sheet (Manufacturer name: Nitto Denko Corporation, Product name: PET substrate ultra-thin 5 μm double-sided tape No. 5600, Thickness: 0.005 mm, Thermal conductivity: 0.10 W/m·K, Specific heat (at 50° C.): 1.31 J/g·K). This double-sided adhesive sheet is obtained by using a PET film as a substrate, and forming adhesive surfaces on both sides of the substrate using an acrylic adhesive.

When the first adhesive layer 83A and the second adhesive layer 83 are formed of extremely thin double-sided adhesive sheets as in Example 8, the thicknesses of the first adhesive layer 83A and the second adhesive layer 83 can be reduced as compared with the thicknesses of the first adhesive layer 13A and the second adhesive layer 13B in Example 1, and thus the thickness of the thermal diffusion member 80 can be reduced.

### Example 9

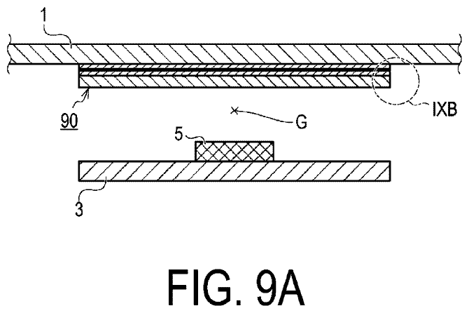

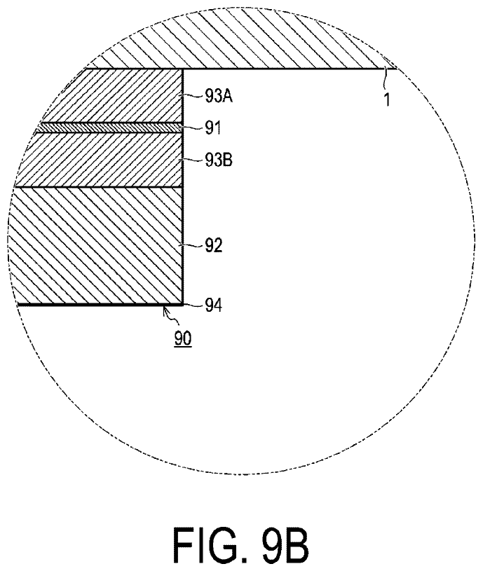

As illustrated in FIG. 9A and FIG. 9B, a thermal diffusion member 90 of Example 9 includes a high-thermal-conductivity layer 91, a low-thermal-conductivity layer 92, a first adhesive layer 93A, a second adhesive layer 93B, and a protective layer 94. These layers are laminated in the order of the first adhesive layer 93A, the high-thermal-conductivity layer 91, the second adhesive layer 93B, the low-thermal-conductivity layer 92, and the protective layer 94, thereby forming a laminated body having a five-layer structure.

In Example 9, the first adhesive layer 93A, the high-thermal-conductivity layer 91, the second adhesive layer 93B, and the low-thermal-conductivity layer 92 are layers formed in a similar manner to the respective layers exemplified in Example 1. The protective layer 94 is formed of a commercially available PET film (Manufacturer name: Toray Industries, Inc., Product name: F53, Thickness: 0.004 mm, Thermal conductivity: 0.30 W/m·K, Specific heat (at 50° C.): 0.32 J/g·K). The total thickness of the thermal diffusion member 90 is 0.649 mm.

### Comparative Example 1

Sheets corresponding to the first adhesive layer 13A and the low-thermal-conductivity layer 12 in Example 1 were laminated in this order to prepare a laminated body having a two-layer structure. A difference from Example 1 is that sheets corresponding to the high-thermal-conductivity layer 11 and the second adhesive layer 13B was omitted. The total thickness of the laminated body of Comparative Example 1 is 0.440 mm.

### Comparative Example 2

Sheets corresponding to the first adhesive layer 13A, the low-thermal-conductivity layer 12, the second adhesive layer 13B, and the high-thermal-conductivity layer 11 in Example 1 were laminated in this order to prepare a laminated body having a four-layer structure. A difference from Example 1 is that the lamination positions of the high-thermal-conductivity layer 11 and the low-thermal-conductivity layer 12 are switched. The total thickness of the laminated body of Comparative Example 2 is 0.605 mm.

### Comparative Example 3

Sheets corresponding to the first adhesive layer 23A, the low-thermal-conductivity layer 22, the second adhesive layer 23B, the high-thermal-conductivity layer 21, and the protective layer 24 in Example 2 were laminated in this order to prepare a laminated body having a five-layer structure. A difference from Example 2 is that the lamination positions of the high-thermal-conductivity layer 21 and the low-thermal-conductivity layer 22 are switched. The total thickness of the laminated body of Comparative Example 3 is 0.635 mm.

### Comparative Example 4

Sheets corresponding to the first adhesive layer 13A, the high-thermal-conductivity layer 11, and the second adhesive layer 13B in Example 1, and a sheet corresponding to a low-thermal-conductivity layer different from that of Example 1 were laminated in this order to prepare a laminated body having a four-layer structure. The low-thermal-conductivity layer in Comparative Example 4 was formed of a commercially available heat insulating sheet (Manufacturer name: Hirose Paper MFG Co., Ltd., Product name: heat insulating paper OS, Thickness: 0.300 mm, Thermal conductivity: 0.05 W/m·K, Specific heat (at 50° C.): 1.88 J/g·K). The total thickness of the laminated body of Comparative Example 4 is 0.605 mm.

### Comparative Example 5

Sheets corresponding to the first adhesive layer 13A, the high-thermal-conductivity layer 11, and the second adhesive layer 13B in Example 1, and a sheet corresponding to a low-thermal-conductivity layer different from that of Example 1 were laminated in this order to prepare a laminated body having a four-layer structure. The low-thermal-conductivity layer in Comparative Example 5 was formed of a commercially available heat insulation sheet (Manufacturer name: 3M Company, Product name: 3M heat insulation tape 8978, Thickness: 0.220 mm, Thermal conductivity: 0.15 W/m·K, Specific heat (at 50° C.): 2.39 J/g·K). The total thickness of the laminated body of Comparative Example 5 is 0.525 mm.

### Comparative Example 6

Sheets corresponding to the first adhesive layer 23A, the high-thermal-conductivity layer 21, the second adhesive layer 23B, and the protective layer 24 in Example 2 were laminated in this order to prepare a laminated body having a four-layer structure. A difference from Example 2 is that the low-thermal-conductivity layer 22 is omitted. Also, a difference from Example 1 can be regarded as being that the low-thermal-conductivity layer 12 in Example 1 is replaced with the protective layer 24 in Example 2. The total thickness of the laminated body of Comparative Example 6 is 0.335 mm.

### Comparative Example 7

Sheets corresponding to the first adhesive layer 13A, the high-thermal-conductivity layer 11, and the second adhesive layer 13B in Example 1, and two sheets of the same sheet as the first adhesive layer 13A that serve as a third adhesive layer and a fourth adhesive layer were laminated in this order to prepare a laminated body having a five-layer structure. A difference from Example 1 is that the third adhesive layer and the fourth adhesive layer, each formed of the same sheet as the first adhesive layer 13A, are provided instead of the low-thermal-conductivity layer 12. The total thickness of the laminated body of Comparative Example 7 is 0.585 mm.

### Performance Test

Each of the above-described laminated bodies of Examples 1 to 6 and Comparative Examples 1 to 7 was subjected to a performance test. The test method is as follows.

As illustrated in FIGS. 1A, 2A, 3A, 4A, 5A, and 6A, the thermal diffusion members 10 to 60 were attached to the inner surface of the casing 1, respectively using the first adhesive layers 13A to 63A included in the thermal diffusion members 10 to 60 of Examples 1 to 6. The electronic circuit board 3 is disposed inside the casing 1, and the heat-generating element 5 (more specifically, a heat-generating electronic component) is mounted on the electronic circuit board 3. The gap between the heat-generating element 5 and the inner surface of the casing 1 is 2 mm. In the above-described test environment, the temperature of the heat-generating element 5 and the temperature of the outer surface of the casing 1 were measured to verify the effect of reducing the temperature of the heat-generating element 5 and the effect of reducing the temperature of the outer surface of the casing 1 by each of the thermal diffusion members 10 to 60. Further, the same verification was performed on the laminated bodies of Comparative Examples 1 to 7. The results are shown in Table 1.

TABLE 1

| | | | Temperature difference (° C.) | |
|---|---|---|---|---|
| | Measurement results (° C.) | | when compared with blank | |
| | Heat-generating | | Heat-generating | |
| | element | Casing | element | Casing |
| Blank | 80.0 | 61.0 | — | — |
| Example 1 | 75.1 | 45.0 | −4.9 | −16.0 |
| Example 2 | 75.7 | 46.8 | −4.3 | −14.2 |
| Example 3 | 76.7 | 44.8 | −3.3 | −16.2 |
| Example 4 | 76.1 | 45.1 | −3.9 | −15.9 |
| Example 5 | 76.3 | 44.6 | −3.7 | −16.4 |
| Example 6 | 76.9 | 44.2 | −3.1 | −16.8 |
| Example 7 | 75.9 | 43.3 | −4.1 | −17.6 |
| Example 8 | 77.3 | 41.5 | −2.7 | −19.4 |
| Example 9 | 77.5 | 46.4 | −2.5 | −14.5 |
| Comparative | 84.0 | 59.6 | 4.0 | −1.4 |
| Example 1 | | | | |
| Comparative | 78.7 | 44.5 | −1.3 | −16.5 |
| Example 2 | | | | |
| Comparative | 78.1 | 45.8 | −1.9 | −15.2 |
| Example 3 | | | | |
| Comparative | 79.4 | 45.5 | −0.6 | −15.5 |
| Example 4 | | | | |
| Comparative | 79.8 | 46.7 | −0.2 | −14.3 |
| Example 5 | | | | |
| Comparative | 78.9 | 44.8 | −1.1 | −16.2 |
| Example 6 | | | | |
| Comparative | 78.2 | 46.5 | −1.8 | −14.5 |
| Example 7 | | | | |

From the test results shown in Table 1, it was suggested that the temperature of the outer surface of the casing 1 could be reduced within a range from 14.2° C. to 16.8° C. in the thermal diffusion members 10 to 60 of Examples 1 to 6. Also, it was suggested that the temperature of the heat-generating element 5 could be reduced within a range from 3.1° C. to 4.9° C. Therefore, by using the thermal diffusion members 10 to 60 of Examples 1 to 6, it is possible to suppress generation of a local high-temperature section in the surface of the casing 1 of the electronic device that includes the built-in heat-generating element 5, and to reduce the temperature of the heat-generating element 5 by 2° C. or more.

A difference between Example 1 and Example 2 is in the presence or absence of the protective layer 24. In Example 2 in which the protective layer 24 is provided, the effect of reducing the temperature of the heat-generating element 5 and the effect of reducing the temperature of the casing 1 are slightly reduced as compared with Example 1 in which the protective layer 24 is not provided, but the performance as the thermal diffusion member is sufficiently secured even in Example 2. Therefore, for example, in a case in which the surface of the low-thermal-conductivity layer 22 or the end surface of each layer forming the thermal diffusion member 20 is easily chipped or scraped off, or in a case in which powder or particulate matter easily falls off from the surface of the low-thermal-conductivity layer 22 or the end surface of each layer forming the thermal diffusion member 20, such a portion may be covered with the protective layer 24. As a result, it is possible to inhibit the heat-generating element 5 and the electronic circuit board 3 from being contaminated by a substance or the like falling off from the thermal diffusion member 20.

A difference between Example 1 and Example 3 is in the material of the low-thermal-conductivity layers 12 and 32, but the performance as the thermal diffusion member is sufficiently secured in both Examples 1 and 3. In Examples 1 and 3, the low-thermal-conductivity layers 12 and 32 are formed of a material having a specific heat lower than that of Comparative Examples 4 to 6. Specifically, in the case of Example 1, the specific heat (at 50° C.) of the low-thermal-conductivity layer 12 is 1.67 J/g·K, and in the case of Example 3, the specific heat (at 50° C.) of the low-thermal-conductivity layer 32 is 1.10 J/g·K. When the low-thermal-conductivity layer is formed of a material having a low specific heat, the low-thermal-conductivity layer becomes the layer having properties of being easily heated and easily cooled. The low-thermal-conductivity layer receives heat from the heat-generating element 5 side to be quickly heated, and at the same time, it releases heat to the high-thermal-conductivity layer side to be quickly cooled. Therefore, it is considered that the amount of heat transferred from the heat-generating element 5 to the high-thermal-conductivity layer via the heated portion in the low-thermal-conductivity layer can be increased, and this contributes to the temperature reduction of the heat-generating element 5.

Although a difference between Example 1 and Examples 4, 5 and 6 is the thickness of the adhesive layer, the performance as the thermal diffusion member is sufficiently secured in any of Examples 1, 4, 5, and 6. Therefore, it was suggested that there was no problem even if the thickness of the adhesive layer was changed within the range indicated in Examples 1, 4, 5, and 6.

In the laminated body of Comparative Example 1, the temperature of the outer surface of the casing 1 could be reduced by only 1.4° C., and the temperature of the heat-generating element 5 was higher than that of the blank. That is, in the laminated body of Comparative Example 1, it was not possible to suppress the generation of the local high-temperature section in the surface of the casing 1 of the electronic device that includes the built-in heat-generating element 5, and it was also not possible to reduce the temperature of the heat-generating element 5 by 2° C. or more. From Comparative Example 1, it was suggested that it was essential to diffuse the heat by using the graphite sheet that serves as the high-thermal-conductivity layer.

In the laminated body of Comparative Example 2, the positions of the low-thermal-conductivity layer 12 and the high-thermal-conductivity layer 11 in the thermal diffusion member 10 of Example 1 are switched. In the laminated body of Comparative Example 3, the positions of the low-thermal-conductivity layer 22 and the high-thermal-conductivity layer 21 in the thermal diffusion member 20 of Example 2 are switched. Even with such a configuration, the temperature of the outer surface of the casing 1 could be reduced within a range from 15.2° C. to 16.5° C., but the temperature of the heat-generating element 5 could be reduced only within a range from 1.3° C. to 1.9° C. That is, even with the laminated bodies of Comparative Examples 2 and 3, the generation of the local high-temperature section in the surface of the casing 1 could be suppressed, but the temperature of the heat-generating element 5 could not be reduced by 2° C. or more. From Comparative Examples 2 and 3, it was suggested that the lamination order of the respective layers is important, and in particular, that the low-thermal-conductivity layer should be disposed on the heat-generating element 5 side and the high-thermal-conductivity layer should be disposed on the casing 1 side.

In the laminated bodies of Comparative Examples 4 to 6, as described above, the low-thermal-conductivity layer is formed of the material having the higher specific heat than those of Examples 1 and 3. Therefore, it is considered to be important to set the specific heat (at 50° C.) of the low-thermal-conductivity layer to 1.67 J/g·K or less, in order to secure the performances as the thermal diffusion member.

In the laminated body of Comparative Example 7, a plurality of the adhesive layers are provided instead of the low-thermal-conductivity layer. The specific heat (at 50° C.) of the adhesive layer is 1.47 J/g·K, and it can be said that the adhesive layer is formed of a low specific heat material similar to those of Examples 1 to 6. However, the thermal conductivity of the adhesive layer is 0.26 W/m·K, which is higher than those of Examples 1 to 6. It was suggested that when such an adhesive layer was used as a substitute for the low-thermal-conductivity layer, the temperature of the heat-generating element 5 could be reduced only by 1.8° C., and the effect of reducing the temperature of the heat-generating element 5 could not be sufficiently obtained.

### OTHER EMBODIMENTS

Although exemplary embodiments have been used to describe the thermal diffusion member above, each of the above-described embodiments is merely an example of one form of the present disclosure. That is, the present disclosure is not limited to the exemplary embodiments described above, and can be carried out in various forms without departing from the technical concept of the present disclosure.

For example, in Examples 1 to 6 described above, as the sheet forming each layer of the thermal diffusion member, a commercially available product of a specific manufacturer is exemplified, but it is needless to say that each layer can be replaced with a sheet having equivalent characteristics.

### Technical Concept Disclosed in Specification

### [Item 1]

A thermal diffusion member being a laminated body including a plurality of layers, including a low-thermal-conductivity layer and a high-thermal-conductivity layer which are laminated. The low-thermal-conductivity layer is formed of a low-thermal-conductivity material sheet having a thermal conductivity of 0.13 to 0.34 W/m·K and a specific heat of 0.9 to 1.67 J/g·K, and the high-thermal-conductivity layer is formed of a graphite sheet having a thermal conductivity of 1500 W/m·K or more in a plane direction of the high-thermal-conductivity layer.

### [Item 2]

In the thermal diffusion member according to Item 1, when the thermal diffusion member is disposed between a casing of an electronic device and a heat-generating element disposed inside the casing, the thermal diffusion member is oriented to cause the high-thermal-conductivity layer to be on a side of the casing and the low-thermal-conductivity layer to be on a side of the heat-generating element, and is disposed at a position at which a gap is formed between the low-thermal-conductivity layer and the heat-generating element.

### [Item 3]

In the thermal diffusion member according to Item 2, the high-thermal-conductivity layer and the low-thermal-conductivity layer are bonded to each other via an adhesive layer, and the adhesive layer is formed of a double-sided adhesive sheet, a thickness of the adhesive layer being in a range from 0.005 to 0.28 mm.

### [Item 4]

In the thermal diffusion member according to any one of Items 1 to 3, a protective layer is provided covering one surface of the low-thermal-conductivity layer on a side opposite to a side of the high-thermal-conductivity layer, and the protective layer is formed of a single-sided adhesive sheet, a thickness of the protective layer being in a range from 0.004 to 0.03 mm.

### [Item 5]

In the thermal diffusion member according to any one of Items 1 to 4, a total thickness of the thermal diffusion member is in a range from 0.048 to 1 mm.

1. A thermal diffusion member being a laminated body comprising:
a plurality of layers including a low-thermal-conductivity layer and a high-thermal-conductivity layer which are laminated, wherein
the low-thermal-conductivity layer is formed of a low-thermal-conductivity material sheet having a thermal conductivity of 0.13 to 0.34 W/m·K and a specific heat of 0.9 to 1.67 J/g·K, and
the high-thermal-conductivity layer is formed of a graphite sheet having a thermal conductivity of 1500 W/m·K or more in a plane direction of the high-thermal-conductivity layer.

2. The thermal diffusion member according to claim 1, wherein
when disposed between a casing of an electronic device and a heat-generating element disposed inside the casing, the thermal diffusion member is oriented to cause the high-thermal-conductivity layer to be on a side of the casing and the low-thermal-conductivity layer to be on a side of the heat-generating element, and is disposed at a position at which a gap is formed between the low-thermal-conductivity layer and the heat-generating element.

3. The thermal diffusion member according to claim 2,
wherein the high-thermal-conductivity layer and the low-thermal-conductivity layer are bonded to each other via an adhesive layer, and
the adhesive layer is formed of a double-sided adhesive sheet, a thickness of the adhesive layer being in a range from 0.005 to 0.28 mm.

4. The thermal diffusion member according to claim 3, wherein
a protective layer is provided covering one surface of the low-thermal-conductivity layer on a side opposite to a side of the high-thermal-conductivity layer, and
the protective layer is formed of a single-sided adhesive sheet, a thickness of the protective layer being in a range from 0.004 to 0.03 mm.

5. The thermal diffusion member according to claim 3, wherein
a total thickness of the thermal diffusion member is in a range from 0.048 to 1 mm.
